(19) United States
(12) Patent Application Publication
(10) Pub. No.: US 2010/0001804 A1
(43) Pub. Date: Jan. 7, 2010

(54) SYSTEM TO IMPROVE A VOLTAGE-CONTROLLED OSCILLATOR AND ASSOCIATED METHODS

(76) Inventors: David M. Friend, Rochester, MN (US); George E. Smith, III, Wappingers Falls, NY (US); Michael Sperling, Poughkeepsie, NY (US); James D. Strom, Rochester, MN (US)

Correspondence Address: INTERNATIONAL BUSINESS MACHINES CORPORATION;Richard Lau, IPLAW DEPARTMENT / Bldg 008-2, 2455 SOUTH ROAD - MS P386, POUGHKEEPSIE, NY, 12601, US

(21) Appl. No.: 12/168,138

(22) Filed: Jul. 6, 2008

(51) Int. Cl. H03L 5/00

(52) U.S. Cl. 331/109

(57) ABSTRACT

A system to improve a voltage-controlled oscillator may include a voltage-controlled oscillator. The system may also include a switch to control a first voltage passing through the voltage-controlled oscillator based upon a digital tune bit used to control the voltage-controlled oscillator's gain.

### FIELD OF THE INVENTION

The invention relates to the field of electronic oscillators, and, more particularly, to voltage-controlled oscillators.

### BACKGROUND OF THE INVENTION

A voltage-controlled oscillator may be used in a broad range of microprocessor and application-specific integrated circuit designs to create, for example, high speed clock signals on-chip. In the past, attempts to control voltage-controlled oscillator gain mostly took the form of analog control of charge pump current as may be disclosed in U.S. Pat. No. 7,271,667 to Gomez, U.S. Pat. No. 6,834,183 to Black et al., and U.S. Pat. No. 6,667,663 to Ozawa.

There are also current-controlled oscillators where the gain may be modified thru some type of current mirroring or unit sources as in U.S. Pat. No. 6,552,618 to Nelson et al., and U.S. Pat. No. 6,466,100 to Mullgrav, Jr. et al. There are also attempts to modify the gain in Inductor-Capacitor Oscillators by switching capacitors in and out in a digital fashion as may be disclosed in U.S. Pat. No. 5,625,325 to Rotzoll et al. and U.S. published application number 2003/0227341 to Sawada.

U.S. Pat. No. 6,850,124 to Li may disclose digital control of inverter-based voltage-controlled oscillator's gain using a design where parallel stacked inverters are added or removed in a digital fashion to change the gain. Such a design may cause the signal to be attenuated, possibly resulting in higher jitter and non-operation at certain frequencies.

U.S. Pat. No. 5,675,293 to Lee et al. may disclose a design where various delays are added into the voltage-controlled oscillator loop digitally. This may change the gain, and may also shift the operating range of the voltage-controlled oscillator.

Alternately, U.S. Pat. No. 5,272,453 to Traynor et al. may disclose digital control to turn off the negative channel field effect transistor tuning, which may change the gain of the voltage-controlled oscillator. However, the design may lose tuning range and possibly affect the duty cycle since only the positive channel field effect transistors are being modulated when the negative channel field effect transistors are removed.

### SUMMARY OF THE INVENTION

In view of the foregoing background, it is an object of the invention to improve a voltage-controlled oscillator and to control its gain.

This and other objects, features, and advantages in accordance with the invention are provided by a system to improve a voltage-controlled oscillator that may include a voltage-controlled oscillator. The system may also include a switch to control a voltage passing through the voltage-controlled oscillator based upon a digital tune bit used to control the voltage-controlled oscillator's gain.

The system may further include a ground rail and/or a power rail to supply the power for the voltage signal passing around the oscillator. The voltage-controlled oscillator may not include an inductor.

The switch may control the voltage-controlled oscillator's gain without shifting the voltage-controlled oscillator's range. The system may further include a data processing unit to generate the digital tune bit remotely from the voltage-controlled oscillator.

The voltage-controlled oscillator may include a first inverting stage, and a second inverting stage connected in series with the first inverting stage. The voltage-controlled oscillator may also include a first switch to control a first voltage passing through the first inverting stage based upon the digital tune bit. The voltage-controlled oscillator may further include a second switch to control the first voltage passing through the second inverting stage based upon the digital tune bit.

The first inverting stage and the second inverting stage may each include an inverter connected in series to a passgate group. Each passgate group may include a first passgate in parallel with a second passgate.

Each of the first passgates may include a transistor on each passgate's gate voltage, respectively. Each of the transistors may include at least one of a negative channel field effect transistor and a complementary positive channel field effect transistor.

The system may also include at least one other inverting stage connected in series with the second inverting stage. The system may further include the other inverting stage comprising an inverter connected to another passgate loop including a third passgate in parallel with a fourth passgate having a transistor on its gate voltage.

Another aspect of the invention is a method to use an improved voltage-controlled oscillator. The method may include providing a voltage-controlled oscillator, and controlling a first voltage passing through the voltage-controlled oscillator based upon a digital tune bit used to control the voltage-controlled oscillator's gain.

The method may also include controlling via the gain of the voltage-controlled oscillator at least one of damping and bandwidth of a closed loop system. The method may further include controlling a plurality of switches using the digital tune bit to control the voltage passing through the voltage-controlled oscillator. In addition, the method may also include routing the passgate voltage either to a ground rail or a power rail based upon each of the plurality of switches' control.

### BRIEF DESCRIPTION OF THE DRAWING

FIG. 1 is a schematic block diagram of a prior art voltage-controlled oscillator.

FIG. 2 is a schematic block diagram of a system to improve a voltage-controlled oscillator in accordance with the invention.

FIG. 3 is a flowchart illustrating method aspects according to the invention.

FIG. 4 is a flowchart illustrating method aspects according to the method of FIG. 3.

FIG. 5 is a flowchart illustrating method aspects according to the method of FIG. 3.

### DETAILED DESCRIPTION OF THE PREFERRED EMBODIMENTS

The invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

As will be appreciated by one skilled in the art, the invention may be embodied as a method, system, or computer program product. Furthermore, the invention may take the form of a computer program product on a computer-usable storage medium having computer-usable program code embodied in the medium.

Any suitable computer usable or computer readable medium may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, or a magnetic storage device.

Computer program code for carrying out operations of the invention may be written in an object oriented programming language such as Java, Smalltalk, C++ or the like. However, the computer program code for carrying out operations of the invention may also be written in conventional procedural programming languages, such as the “C” programming language or similar programming languages.

The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the Internet using an Internet Service Provider).

The invention is described below with reference to flowchart, illustrations, and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

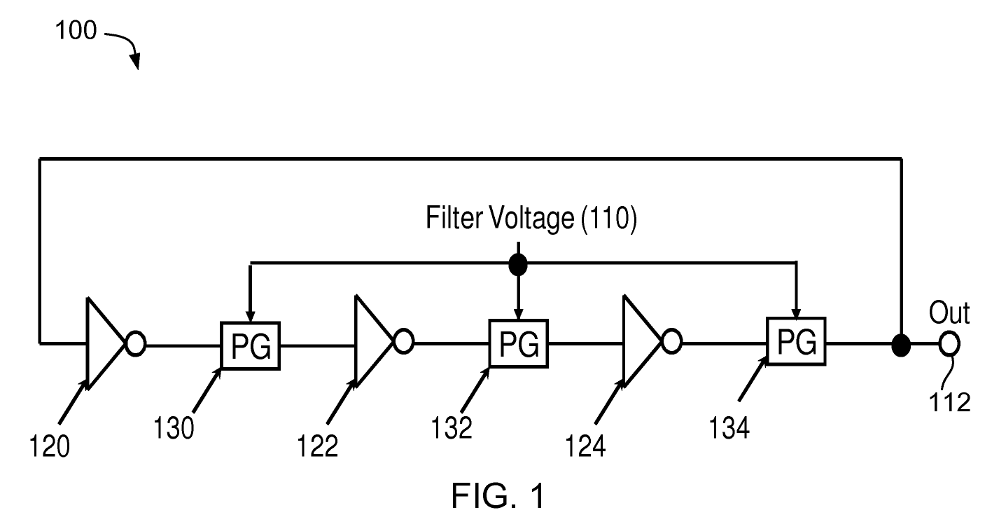

Referring to FIG. 1, a prior art voltage-controlled oscillator 100 is illustrated. The basic design of any of these prior art voltage-controlled oscillators 100 is a loop of inverting stages with some type of tuning element. Usually either the capacitance or resistance between the stages is modified based on an input voltage.

The drawback to such solutions is that the gain of the voltage-controlled oscillator 100 is essentially fixed. The voltage comes straight from a loop filter and therefore cannot be changed between the filter and oscillator.

For instance, if the gain is too high, it will result in a large amount of jitter at the output. Alternately, if the gain is too low, the range will be sacrificed.

Efforts to address this issue usually involve some type of analog control on the filter voltage to tune the gain to an acceptable range, or changing to other oscillator topologies, such as current-controlled oscillators where fine-tuning may be better controlled. Both of these efforts require additional circuitry including analog voltage to current converters or analog buffers. This adds complexity and may require additional tuning so that these circuits work as expected.

In FIG. 1, a filter voltage 110 is connected to passgates 130, 132, and 134 and controls the speed of the oscillation of the three stage ring oscillator, composed of inverters 120, 122, and 124. An output voltage 112 will rise and fall from the power supply voltage to the ground voltage at a frequency determined by the gain of the oscillator multiplied by the value of the filter voltage. The gain will be a function of the transistor characteristics and therefore change when the transistor parameters change.

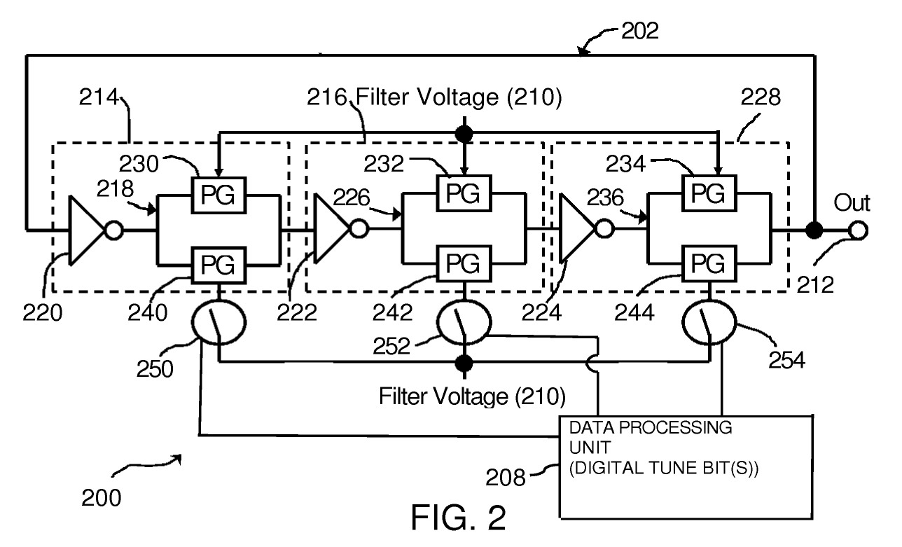

Referring to FIG. 2, a system 200 to improve a voltage-controlled oscillator 202 in accordance with the invention is initially described. The voltage-controlled oscillator 202 (“VCO”) includes a switch such as 250, 252, and 254 to control a voltage such as filter voltage 210, which affects the delay of the voltage signal passing through the voltage-controlled oscillator based upon a digital tune bit used to control the voltage-controlled oscillator's gain, for example.

In one embodiment, the voltage-controlled oscillator 202 further includes a ground rail and/or a power rail to supply the power for the voltage signal passing around the oscillator. In another embodiment, the voltage-controlled oscillator 202 does not include an inductor as modern integrated circuits may not be able to afford the wiring overhead of on-chip inductance. Additionally, the range of an oscillator containing an inductor may be too low for applications such as system 200.

The switch 250, 252, and 254 controls the voltage-controlled oscillator 202's gain without shifting the voltage-controlled oscillator's range, for example. In one embodiment, the system 200 further includes a data processing unit 208 to generate the digital tune bit remotely for the voltage-controlled oscillator 202. In other words, digital switching is advantageous since tuning bits that are set elsewhere on-chip may then control the voltage-controlled oscillator 202.

The voltage-controlled oscillator 202 includes a first inverting stage 214, and a second inverting stage 216 connected in series with the first inverting stage, for example. The voltage-controlled oscillator 202 also includes a first switch 250 to control a voltage 210 connected to the gate of passgate 240. This filter voltage 210 affects the delay of the voltage signal passing through the first inverting stage 214 based upon the digital tune bit, for instance. The voltage-controlled oscillator 202 further includes a second switch 252 to control a voltage 210 connected to the gate of passgate 242. This filter voltage 210 affects the delay of the voltage signal passing through the second inverting stage 216 based upon the digital tune bit, for example.

The first inverting stage 214 and the second inverting stage 216 each include an inverter 220 and 222 connected in series to a passgate group 218 and 226, respectively, for example. Each passgate group 218 and 226 includes a first passgate 230 and 232 in parallel with a second passgate group 240 and 242, respectively, for instance.

In one embodiment, each of the first passgates 230 and 232 includes a switch 250 and 252 comprising a transistor on each passgate's gate voltage, respectively. By using transistors as switches, the gain can be digitally controlled by switching in as many passgates as necessary. In another embodiment, each of the transistors comprises a negative channel field effect transistor and/or a complementary positive channel field effect transistor.

In one embodiment, the system 200 includes at least one other inverting stage 228 connected in series with the second inverting stage 226. In another embodiment, the other inverting stage 228 includes an inverter 224 connected to another passgate group 236 including a third passgate 234 in parallel with a fourth passgate 244 comprising a transistor on its gate voltage.

In view of the foregoing, the system 200 improves a voltage-controlled oscillator 202 and digitally controls its gain. Controlling the gain of such a voltage-controlled oscillator 202 is important in applications like phase-locked loops where tuning range and jitter may be traded off thru gain adjustments, and/or loop parameters may be tuned to control damping and bandwidth via the gain if desired.

The system 200 is especially useful in applications that require large tuning ranges (over 4:1) and low sensitivity to process variability. The system 200 therefore provides new functionality and has minimal overhead and is less complex compared to previous solutions.

In addition, the tuning range of the voltage-controlled oscillator 202 will be extended instead of shifted and all the signals will remain full-swing, meaning they will switch from the power rail to the ground rail and back. This will mean better signal transmission and reduced jitter.

For example, if the switches 250, 252, and 254 are left open, only passgates 240, 242, and 244 will provide a resistive path thru the voltage-controlled oscillator 202. If the switches 250, 252, and 254 are connected, all passgates 230, 232, 234, 240, 242, and 244 will be conducting and the gain will be higher.

This is due to the fact that for the same filter voltage 210 the voltage-controlled oscillator 202 composed of inverters 220, 222, and 224 will be able to run faster due to less resistance. Therefore, the output voltage 212 will be enabled to output a higher frequency than the base design.

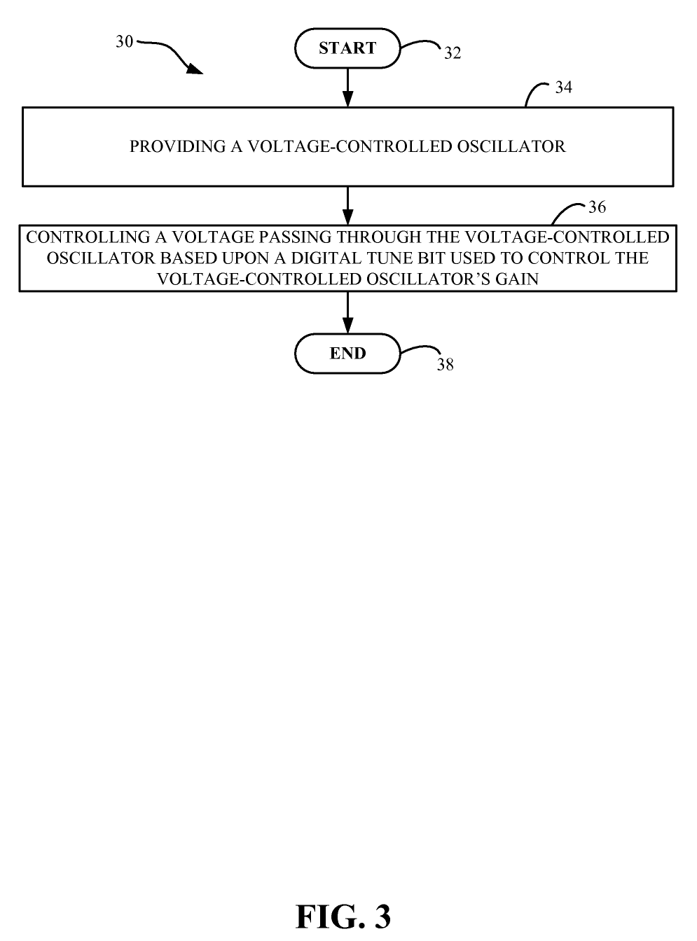

Another aspect of the invention is a method to use an improved voltage-controlled oscillator, which is now described with reference to flowchart 30 of FIG. 3. The method begins at Block 32 and may include providing a voltage-controlled oscillator at Block 34. The method may also include controlling a voltage passing through the voltage-controlled oscillator based upon a digital tune bit used to control the voltage-controlled oscillator's gain at Block 36. The method ends at Block 38.

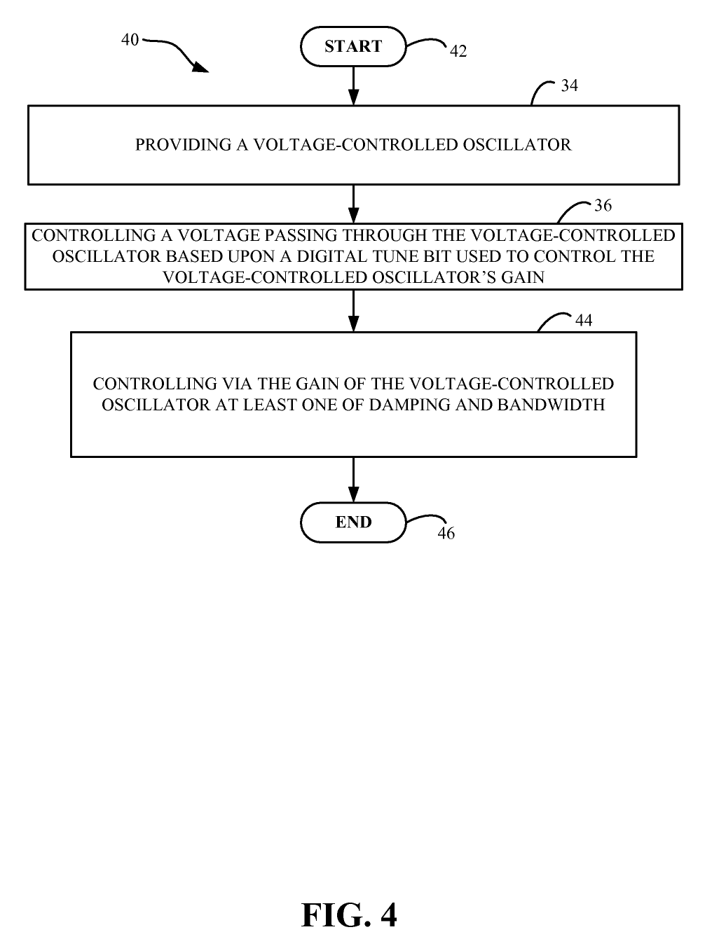

In another method embodiment, which is now described with reference to flowchart 40 of FIG. 4, the method begins at Block 42. The method may include the steps of FIG. 3 at Blocks 34 and 36. The method may further include controlling via the gain of the voltage-controlled oscillator at least one of damping and bandwidth at Block 44, such as when used in a closed loop system. The method ends at Block 46.

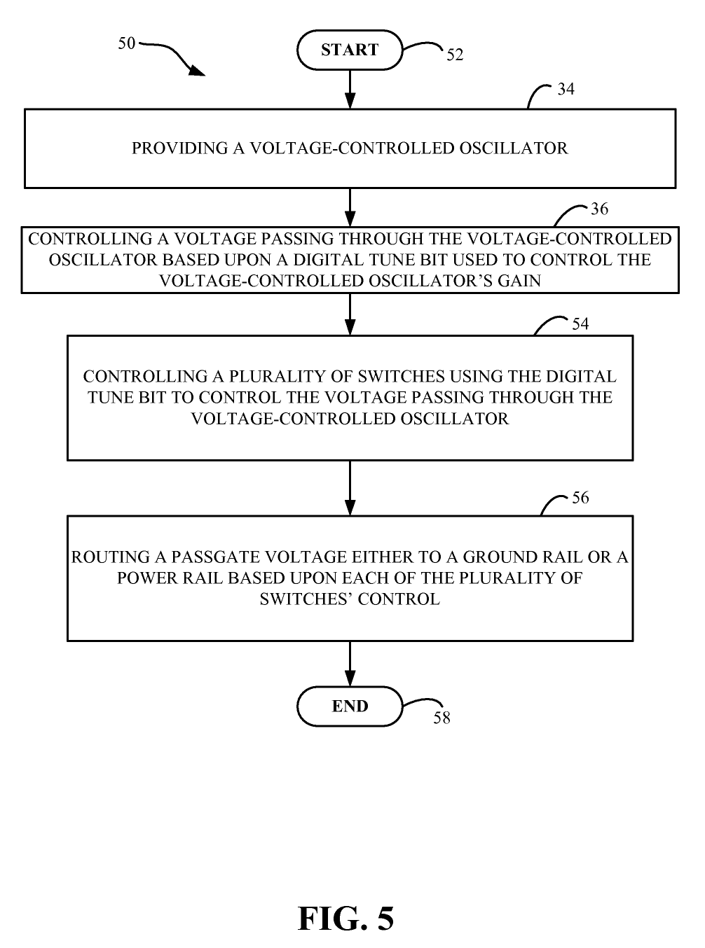

In another method embodiment, which is now described with reference to flowchart 50 of FIG. 5, the method begins at Block 52. The method may include the steps of FIG. 3 at Blocks 34 and 36. The method may further include controlling a plurality of switches using the digital tune bit to control the voltage passing through the voltage-controlled oscillator at Block 54. The method may additionally include routing a passgate voltage either to a ground rail or a power rail based upon each of the plurality of switches' control at Block 56. The method ends at Block 58.

The capabilities of the system 200 can be implemented in software, firmware, hardware or some combination thereof.

The flow diagrams depicted herein are just examples. There may be many variations to these diagrams or the steps (or operations) described therein without departing from the spirit of the invention. For instance, the steps may be performed in a differing order, or steps may be added, deleted or modified. All of these variations are considered a part of the claimed invention. Furthermore, the use of the terms a, an, etc. do not denote a limitation of quantity, but rather denote the presence of at least one of the referenced item.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

That which is claimed is:

1. A system to improve a voltage-controlled oscillator, the system comprising:
a voltage-controlled oscillator; and
a switch to control a first voltage passing through said voltage-controlled oscillator based upon a digital tune bit used to control said voltage-controlled oscillator's gain.

2. The system of claim 1 wherein said voltage-controlled oscillator does not include an inductor.

3. The system of claim 1 wherein said switch controls said voltage-controlled oscillator's gain without shifting said voltage-controlled oscillator's range.

4. The system of claim 1 further comprising a data processing unit to generate the digital tune bit remotely from {the phrase “remotely from” indicates a location away from the voltage-controlled oscillator, e.g. off chip, rather than where the tune bit is sent to be used} said voltage-controlled oscillator.

5. The system of claim 1 wherein said voltage-controlled oscillator includes:
a first inverting stage;
a second inverting stage connected in series with said first inverting stage;
a first switch to control a second voltage that effects the first voltage passing through said first inverting stage based upon the digital tune bit; and
a second switch to control a third voltage that effects the first voltage passing through said second inverting stage based upon the digital tune bit.

6. The system of claim 5 wherein said first inverting stage and said second inverting stage each includes an inverter connected in series to a passgate group.

7. The system of claim 6 wherein each passgate group includes a first passgate in parallel with a second passgate.

8. The system of claim 7 wherein each of said first passgates include a transistor on each passgate's gate voltage, respectively.

9. The system of claim 9 wherein each of said transistors comprises at least one of a negative channel field effect transistor and a complementary positive channel field effect transistor.

10. The system of claim 5 further comprising at least one other inverting stage connected in series with said second inverting stage, said at least one other inverting stage comprising an inverter connected to another passgate group including a third passgate in parallel with a fourth passgate having a transistor on its gate voltage.

11. A method of using an improved voltage-controlled oscillator, the method comprising:
providing a voltage-controlled oscillator; and
controlling a first voltage passing through the voltage-controlled oscillator based upon a digital tune bit used to control the voltage-controlled oscillator's gain.

12. The method of claim 11 further comprising controlling via the gain of the voltage-controlled oscillator at least one of damping and bandwidth.

13. The method of claim 11 wherein the switch controls the voltage-controlled oscillator's gain without shifting the voltage-controlled oscillator's range.

14. The method of claim 11 further comprising controlling a plurality of switches using the digital tune bit to control the first voltage passing through the voltage-controlled oscillator.

15. The method of claim 14 further comprising routing a passgate voltage either to a ground rail or a power rail based upon each of the plurality of switches' control.

16. The method of claim 14 wherein each of the plurality of switches includes a transistor that uses the digital tune bit.

17. A system to improve a voltage-controlled oscillator, the system comprising:
a voltage-controlled oscillator without an inductor;
a switch to control a first voltage passing through said voltage-controlled oscillator based upon a digital tune bit used to control said voltage-controlled oscillator's gain;
a first inverting stage;
a second inverting stage connected in series with said first inverting stage;
a first switch to control the first voltage which affects a second voltage passing through said first inverting stage based upon the digital tune bit; and
a second switch to control the first voltage which affects a third voltage passing through said second inverting stage based upon the digital tune bit.

18. The system of claim 17 wherein said switch controls said voltage-controlled oscillator's gain without shifting said voltage-controlled oscillator's range.

19. The system of claim 17 further comprising a data processing unit to generate the digital tune bit remotely from said voltage-controlled oscillator.
